(19) United States
(12) Patent Application Publication
(10) Pub. No.: US 2023/0345634 A1
(43) Pub. Date: Oct. 26, 2023

(54) DIFFERENTIAL VIA DESIGN ON A PRINTED CIRCUIT BOARD

(71) Applicant: Dell Products L.P., Round Rock, TX (US)

(72) Inventors: Chang-Kai Chu, Zhongli District (TW); Chang-Hsien Chen, New Taipei City (TW); Bhyrav Mutnury, Austin, TX (US)

(21) Appl. No.: 17/726,235

(22) Filed: Apr. 21, 2022

(51) Int. Cl. H05K 1/11; H05K 3/40

(52) U.S. Cl. CPC H05K 1/115; H05K 3/4038; H05K 2201/09545

(57) ABSTRACT

An information handling system includes a printed circuit board having a signal via fabricated through the printed circuit board. The signal via includes a conductive metal plating. The signal via also includes first and second via portions. The first via portion is connected to a first trace of a differential pair. The second via portion is connected to a second trace of the differential pair. The first and second via portions are formed in the conductive metal plating.

### FIELD OF THE DISCLOSURE

The present disclosure generally relates to information handling systems, and more particularly relates to a differential via design on a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a printed circuit board having a signal via fabricated through the printed circuit board. The signal via includes a conductive metal plating. The signal via also includes first and second via portions. The first via portion may be connected to a first trace of a differential pair. The second via portion may be connected to a second trace of the differential pair. The first and second via portions may be formed in the conductive metal plating.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a portion of a printed circuit board with signal vias connected to pads of a differential pair according to prior art;

FIG. 2 is a diagram of a portion of a printed circuit board with differential signal via connected to pads of a differential pair according to at least one embodiment of the present disclosure;

FIG. 3 is a diagram of a differential signal via according to at least one embodiment of the present disclosure;

FIG. 4 is a flow diagram of a method for creating a different signal via and connecting the differential signal via to pads of a differential pair according to at least one embodiment of the present disclosure; and

FIG. 5 is a block diagram of a general information handling system according to an embodiment of the present disclosure;

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

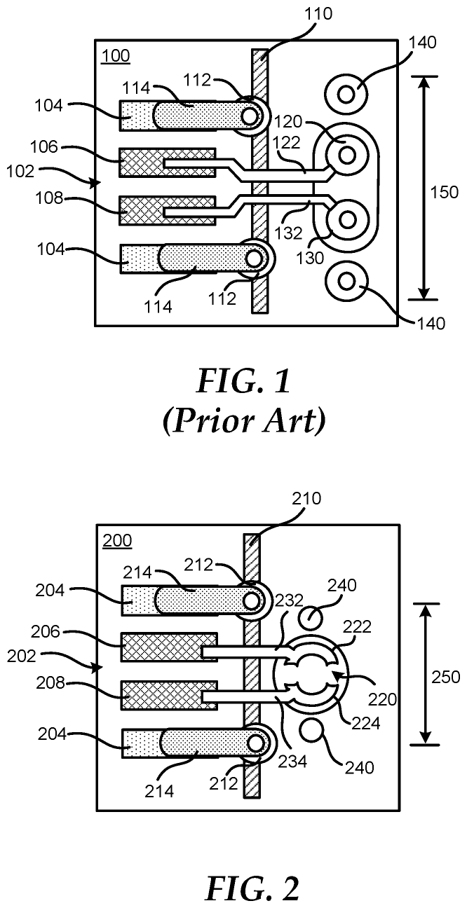

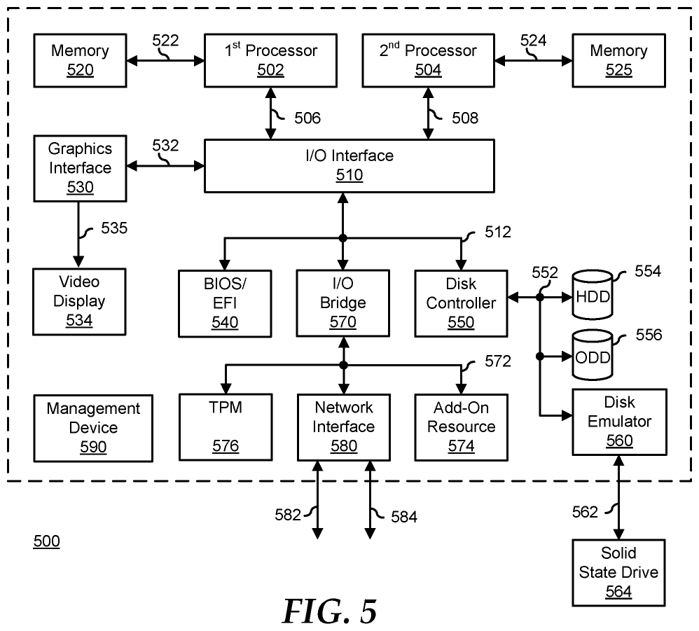

FIG. 1 illustrates a printed circuit board (PCB) 100 of an information handling system, such as information handling system 500 of FIG. 5, according to prior art in the field. For purpose of this disclosure information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a laptop computer, a smart phone, a tablet device or other consumer electronic device, a network server, a network storage device, a switch, a router, or another network communication device, or any other suitable device and may vary in size, shape, performance, functionality, and price.

PCB 100 includes a differential pair 102 and ground pads 104. Differential pair 102 includes pads 106 and 108. Each ground pad 104 may be physically and electrically coupled to a ground layer 110 of PCB 100 by a respective ground via 112 and ground trace 114. PCB 100 also includes signal vias 120 and 130. Signal via 120 is electrically and physically connected to pad 106 of differential pair 102 by a signal trace 122. Similarly, signal via 130 is electrically and physically connected to pad 108 of differential pair 102 by a signal trace 132. PCB 100 further includes ground vias 140 associated with signal vias 120 and 130. Ground vias 140, signal via 120, and signal via 130 may cover a particular length 150 on PCB 100.

In an example, a combination of ground pad 104, ground plane layer 110, ground via 112, and ground trace 114 may reduce crosstalk between differential pair 102 and an adjacent differential pair. The details of PCB manufacture, and particularly the forming of vias and traces on a PCB are known in the art and will not be further described herein, except as needed to illustrate the current embodiments.

PCB 100 may be utilized for transmission of high speed signals. In this situation, routing for the high speed signal on PCB 100 may need a lot of differential vias for signals. Additionally, PCB 100 may include a lot of ground vias to control a target impedance of a differential pair and to reduce crosstalk between adjacent differential pairs. The via design of PCB 100 may utilize via to via spacing to control the impedance of the differential pair, and may add one or more grounds vias to reduce crosstalk. This via design in PCB 100 may utilize a lot of routing space available in the PCB. In some cases, traditional differential via designs may exceed an available real estate for routing on PCB 100 when there is high density PCB routing.

FIG. 2 illustrates a portion of a PCB 200 of an information handling system, such as information handling system 500 of FIG. 5, according to at least one embodiment of the present disclosure. PCB 200 includes a differential pair 202 and ground pads 204. Differential pair 202 includes pads 206 and 208. Each ground pad 204 may be physically and electrically coupled to a ground layer 210 of PCB 200 by a respective ground via 212 and ground trace 214. PCB 200 also includes signal via 220, which in turn is divided into separate via portions 222 and 224. Signal via portion 222 is electrically and physically connected to pad 206 of differential pair 202 by a signal trace 232. Similarly, signal via portion 224 is electrically and physically connected to pad 208 of differential pair 202 by a signal trace 234. PCB 200 further includes ground vias 240 associated with signal via portions 222 and 224 of via 220. Ground vias 240, signal via 220 may cover a particular length 250 on PCB 200.

Signal via 220 (portions 222 and 224) and ground vias 212 and 240 are utilized to interconnect two or more different metal layers within PCB 200. Additionally, signal via 220 and ground vias 212 and 240 may be utilized to connect the two or more different metal layers within PCB 200 with metal traces and/or metal pads on a surface of the PCB, such as pads 204, 206, and 208. While portions 222 and 224 of signal via 220 are illustrated and described as connected metal layers within PCB 200 to respective pads 206 and 208 via respective traces 232 and 234 on the surface of the PCB, traces 232 and 234 may be located within any layer within the PCB and portions 222 and 224 of signal via 220 may perform substantially similar functions without varying from the scope of this disclosure.

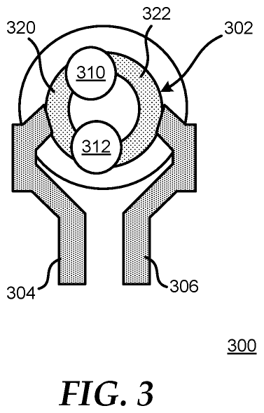

In an example, signal via 220 with via portions 222 and 224 may create a smaller structure as compared to signal vias 120 and 130 of PCB 100 in FIG. 1. For example, length 150 consumed by ground vias 140 and signal vias 120 and 130 on PCB 100 of FIG. 1 is greater than length 250 consumed by ground vias 240 and signal via portions 222 and 224 of signal via 220 on PCB 200. Thus, the layout space of signal via 220 and ground vias 240 on PCB 200 is less than the layout space of signal vias 120 and 130 and ground vias 140 on PCB 100 of FIG. 1. In this example, the structure of signal via 220 with via portions 222 and 224 may enable a greater density of vias and signal traces on PCB 200 as compared to the density of vias and signal traces on PCB 100 of FIG. 1. The fabrication of a differential signal via with two via portions, such as a via substantially similar to signal via 220 with via portions 222 and 224 will be described with respect to FIG. 3.

FIG. 3 illustrates a differential signal via 300 according to at least one embodiment of the present disclosure. Differential signal via 300 includes a plated signal via 302, and differential traces 304 and 306. In an example, signal via 302 may be plated with any suitable conductive material including, but not limited to, copper, silver, gold, zinc, and nickel. The details of PCB manufacture, and particularly the forming of vias in a PCB are known in the art and will not be further described herein, except as needed to illustrate the current embodiments.

After signal via 302 has been plated, two sections 310 and 312 of the plating of the signal via may be removed in any suitable manner. For example, a drill may be utilized to drill holes corresponding to sections 310 and 312 in signal via 302 as shown in FIG. 3. After sections 310 and 312 are removed from signal via 302, the signal via is separated into via portions 320 and 322. In an example, via portion 320 may be physically and electrically connected to differential trace 304 and via portion 322 may be physically and electrically connected to differential trace 306. In this example, via portions 320 and 322 may perform substantially the same function as respective signal vias 120 and 130 of FIG. 1, but may consume substantially less space on a PCB.

In an example, removed sections 310 and 312 would preferably be located along a line of symmetry for signal via 302, such that via portions 320 and 322 may be the same size. In an exemplary embodiment, the outer diameter of signal via 302 may be 25 mil and the diameter each of sections 310 and 312 may be 15 mil. In this embodiment, a distance from the center of section 310 to the center of section 312 may be 25 mil, a distance from the center of section 310 to the center of signal via 302 may be 12.5 mil, and a distance from the center of section 312 to the center of signal via 302 may be 12.5 mil. Additionally, in this embodiment, a distance from an inner edge of section 310 to an inner edge of section 312 may be 5 mil, a minimum spacing from an edge of section 310 to trace 304 or 306 may be 4 mil, and a minimum spacing from an edge of section 312 to trace 304 or 306 may be 4 mil. One of ordinary skill in the art would recognize that mil is a unit of measurement utilized in routing on PCBs, and one mil equals one-thousandth of an inch or two hundred fifty four ten-thousandths of a millimeter.

However, the locations for a drill to remove sections 310 and 312 may vary slightly, within a tolerance of +/−2 mil, in one or more directions from a desired drilling location. For example, the drill hole for removed section 310 may be slightly to the left of the line of symmetry for signal via 302, and the drill hole for removed section 312 may also be slightly to the left of the line of symmetry as shown in FIG. 3. In this example, via portion 322 may include more of the plating of signal via 302 than via portion 320. In an example, a tolerance of the drill location for removed sections 310 and 312 may be such that both via portions 320 and 322 may always include enough of the plating of signal via 302 to have a desired impedance, such as 85 ohms+/−10%, and operate has needed for a differential pair.

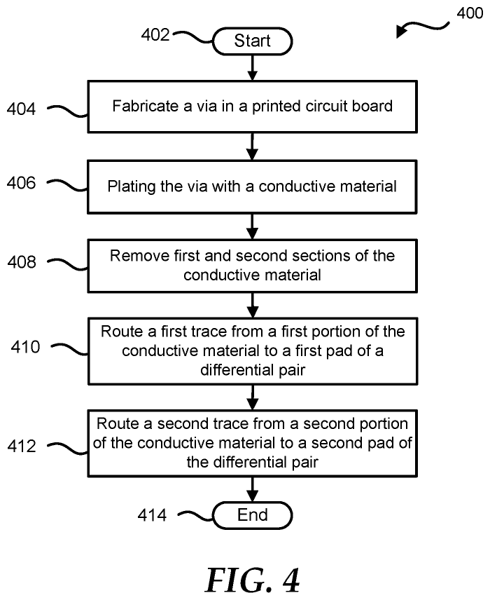

FIG. 4 is a flow diagram of method 400 for creating a different signal via and connecting the differential signal via to pads of a differential pair according to at least one embodiment of the present disclosure, starting a block 402. It will be readily appreciated that not every method step set forth in this flow diagram is always necessary, and that certain steps of the methods may be combined, performed simultaneously, in a different order, or perhaps omitted, without varying from the scope of the disclosure.

At block 404, a via is fabricated in a PCB. In an example, the via may be any suitable type of via including, but not limited to, a through hole via, a micro via, and a skip via. At block 406, the via is plated with a conductive material. In an example, the conductive material may be copper. The details of PCB manufacture, and particularly the forming of vias and traces on a PCB are known in the art and will not be further described herein, except as needed to illustrate the current embodiments.

At block 408, first and second sections of the conductive material plated on the via are removed. In an example, the first and second sections may be removed by any suitable manner, such as drilling the first and second sections out of the conductive material or the like. In certain examples, the removal of the first and second sections may create first and second portions of the conductive material plated on the via. At block 410, a first trace is routed from the first portion of the conductive material to a first pad of a differential pair. At block 412, a second trace is routed from the second portion of the conductive material to a second pad of the differential pair, and the flow ends at block 414. In an example, the electrical communication from the first pad to the first portion of the conductive material through the first trace may provide a first signal path for a differential signal transmitted on the differential pair. The electrical communication from the second pad to the second portion of the conductive material through the second trace may provide a second signal path for the differential signal.

FIG. 5 illustrates a generalized embodiment of an information handling system 500. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below, and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 562, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 562, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532, and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 1394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512, or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (00B) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500. Management device 590 can operate off of a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like.

Management device 590 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board of an information handling system, the printed circuit board comprising:
a signal via fabricated through the printed circuit board, wherein the signal via includes a conductive metal plating, the signal via includes;
a first via portion connected to a first trace of a differential pair; and
a second via portion connected to a second trace of the differential pair, wherein the first and second via portions are formed in the conductive metal plating.

2. The printed circuit board of claim 1, wherein first and second sections of the conductive metal plating is removed to form the first and second via portions.

3. The printed circuit board of claim 2, further comprising:
a first ground via located on a first side of the signal via nearest the first via portion.

4. The printed circuit board of claim 3, further comprising:
a second ground via located on a second side of the signal via nearest the second via portion.

5. The printed circuit board of claim 2, wherein the first and second sections are removed along a line of symmetry of the signal via.

6. The printed circuit board of claim 5, wherein the first and second portions are substantially similar in size based on the first and second sections being removed along the line of symmetry of the signal via.

7. The printed circuit board of claim 2, the first and second sections are removed at respective locations of the conductive metal plating that is offset from a line of symmetry of the signal via.

8. The printed circuit board of claim 7, wherein the first and second portions are different sizes based on the first and second sections being offset from the line of symmetry of the signal via.

9. An information handling system comprising:
a printed circuit board including:
first and second pads of a differential pair; and
a signal via fabricated through the printed circuit board, wherein the signal via includes a conductive metal plating, the signal via includes;
a first via portion connected by a first trace to the first pad of the differential pair; and
a second via portion connected by a second trace to the second pad of the differential pair, wherein the first and second via portions are formed in the conductive metal plating.

10. The information handling system of claim 9, wherein first and second sections of the conductive metal plating is removed to form the first and second via portions.

11. The information handling system of claim 10, wherein the printed circuit board further comprises:
a first ground via located on a first side of the signal via nearest the first via portion.

12. The information handling system of claim 11, wherein the printed circuit board further comprises:
a second ground via located on a second side of the signal via nearest the second via portion.

13. The information handling system of claim 10, wherein the first and second sections are removed along a line of symmetry of the signal via.

14. The information handling system of claim 13, wherein the first and second portions are substantially similar in size based on the first and second sections being removed along the line of symmetry of the signal via.

15. The information handling system of claim 10, the first and second sections are removed at respective locations of the conductive metal plating that is offset from a line of symmetry of the signal via.

16. The information handling system of claim 7, wherein the first and second portions are different sizes based on the first and second sections being offset from the line of symmetry of the signal via.

17. A method comprising:
fabricating a signal via in a printed circuit board of an information handling system;
plating the signal via with a conductive material;
removing first and second sections of the signal via to create first and second via portions of the signal via;
routing a first trace from the first portion to a first pad of a differential pair; and
routing a second trace from the second portion to a second pad of the differential pair.

18. The method of claim 17, wherein an electrical communication from the first pad to the first portion of the conductive material through the first trace may provide a first signal path for a differential signal transmitted on the differential pair.

19. The method of claim 18, wherein an electrical communication from the second pad to the second portion of the conductive material through the second trace may provide a second signal path for the differential signal.

20. The method of claim 17, further comprising:
fabricating a first ground via in the printed circuit board, wherein the first ground via is located on a first side of the signal via; and
fabricating a second ground via in the printed circuit board, wherein the second ground via is located on a second side of the signal via.
